(19) United States
(12) Patent Application Publication
(10) Pub. No.: US 2024/0079300 A1
(43) Pub. Date: Mar. 7, 2024

(54) SEMICONDUCTOR PACKAGE

(71) Applicant: SAMSUNG ELECTRONICS CO., LTD., Suwon-si (KR)

(72) Inventor: Youngbae KIM, Suwon-si (KR)

(73) Assignee: SAMSUNG ELECTRONICS CO., LTD., Suwon-si (KR)

(21) Appl. No.: 18/242,917

(22) Filed: Sep. 6, 2023

(30) Foreign Application Priority Data
Sep. 6, 2022 (KR) 10-2022-0113024

(51) Int. Cl. H01L 23/498; H01L 23/31; H01L 25/065

(52) U.S. Cl. CPC H01L 23/49816; H01L 23/3107; H01L 23/49838; H01L 25/0657; H01L 2225/06541

(57) ABSTRACT

A semiconductor package is provided. The semiconductor package includes: a wiring board including a base substrate layer, and solder masks and a plurality of solder ball lands provided on the base substrate layer; a chip provided on and electrically connected to the wiring board; a molding layer provided on the chip and the wiring board; and a plurality of solder balls arranged on a lower surface of the wiring board and fused with the plurality of solder ball lands. The plurality of solder ball lands include a plurality of solder mask defined (SMD) type solder ball lands having side surfaces in contact with the solder masks, and a plurality of non-solder mask defined (NSMD) type solder ball lands that are separated from the solder masks to define an open area that exposes the base substrate layer.

### CROSS-REFERENCE TO RELATED APPLICATION

This application claims priority to Korean Patent Application No. 10-2022-0113024, filed on Sep. 6, 2022, in the Korean Intellectual Property Office, the disclosure of which is incorporated herein by reference in its entirety.

### BACKGROUND

The present disclosure relates to a semiconductor package, and more particularly, to a semiconductor package including a plurality of solder balls.

A semiconductor package may include a chip mounted on an upper surface of a wiring board, a molding layer provided around the chip, and solder balls arranged on a lower surface of the wiring board. The semiconductor package may be electrically connected to a board substrate using the solder balls arranged on the lower surface of the wiring board. Accordingly, in the semiconductor package, mechanical and electrical reliability of the solder balls connected to the board substrate is important.

### SUMMARY

One or more example embodiments provide a semiconductor package capable of increasing mechanical and electrical reliability of solder balls.

According to an aspect of an example embodiment, a semiconductor package includes: a wiring board including a base substrate layer, and solder masks and a plurality of solder ball lands provided on the base substrate layer; a chip provided on and electrically connected to the wiring board; a molding layer provided on the chip and the wiring board; and a plurality of solder balls arranged on a lower surface of the wiring board and fused with the plurality of solder ball lands. The plurality of solder ball lands include a plurality of solder mask defined (SMD) type solder ball lands having side surfaces in contact with the solder masks, and a plurality of non-solder mask defined (NSMD) type solder ball lands that are separated from the solder masks to define an open area that exposes the base substrate layer.

According to an aspect of an example embodiment, a semiconductor package including: a wiring board including a base substrate layer, and solder masks and a plurality of solder ball lands provided on the base substrate layer; a chip provided on and electrically connected to the wiring board; a molding layer provided on the chip and the wiring board; and a plurality of solder balls arranged on a lower surface of the wiring board and fused with the plurality of solder ball lands. The plurality of solder ball lands include a plurality of solder mask-defined (SMD) type solder ball lands of which outer portions are in contact with the solder masks, and a plurality of non-solder mask defined (NSMD) type solder ball lands of which outer portions are exposed by open areas between the plurality of NSMD type solder ball lands and the solder masks.

According to an aspect of an example embodiment, a semiconductor package includes: a wiring board including a base substrate layer, a plurality of solder masks under the base substrate layer, a plurality of solder mask-defined (SMD) type solder ball lands arranged between the plurality of solder masks, and a plurality of non-solder mask defined (NSMD) type solder ball lands each arranged between the plurality of solder masks, wherein the base substrate layer is exposed between the plurality of NSMD type solder ball lands and the plurality of solder masks; a chip provided on and electrically connected to the wiring board; a molding layer provided on the chip and the wiring board; a plurality of solder balls fused with the plurality of SMD type solder ball lands and the plurality of NSMD type solder ball lands; and a substrate including a plurality of conductive pads fused with the plurality of solder balls.

### BRIEF DESCRIPTION OF DRAWINGS

The above and other aspects, features, and advantages will be more clearly understood from the following description, taken in conjunction with the accompanying drawings, in which:

FIG. 1 is a cross-sectional view illustrating a semiconductor package according to example embodiments;

FIG. 2 is a partially enlarged view of the semiconductor package of FIG. 1;

FIGS. 3 and 4 are plan views illustrating solder ball lands on a wiring board of the semiconductor packages of FIGS. 1 and 2;

FIG. 5 is a plan view illustrating an arrangement of solder ball lands on a wiring board of a semiconductor package according to example embodiments;

FIG. 6 is a plan view illustrating an arrangement of solder ball lands on a wiring board of a semiconductor package according to example embodiments;

FIG. 7 is a plan view illustrating an arrangement of solder ball lands on a wiring board of a semiconductor package according to example embodiments;

FIG. 8 is a cross-sectional view illustrating a semiconductor package according to example embodiments;

FIG. 9 is a cross-sectional view illustrating a semiconductor package according to example embodiments;

FIG. 10 is a plan view illustrating an arrangement of solder ball lands on a wiring board of a semiconductor package according to example embodiments;

FIG. 11 is a plan view illustrating an arrangement of solder ball lands on a wiring board of a semiconductor package according to example embodiments;

FIG. 12 is a plan view illustrating an arrangement of solder ball lands on a wiring board of a semiconductor package according to example embodiments;

FIG. 13 is a cross-sectional view illustrating a semiconductor package according to example embodiments;

FIG. 14 is a cross-sectional view illustrating a semiconductor package according to example embodiments;

FIG. 15 is a block diagram illustrating a configuration of a semiconductor package according to example embodiments; and

FIG. 16 is a block diagram schematically illustrating a configuration of a semiconductor package according to example embodiments.

### DETAILED DESCRIPTION

Hereinafter, example embodiments will be described in detail with reference to the accompanying drawings. Each example embodiment provided in the following description is not excluded from being associated with one or more features of another example or another example embodiment also provided herein or not provided herein but consistent with the present disclosure. It will be understood that when an element or layer is referred to as being “on,” “connected to” or “coupled to” another element or layer, it can be directly on, connected or coupled to the other element or layer, or intervening elements or layers may be present. By contrast, when an element is referred to as being “directly on,” “directly connected to” or “directly coupled to” another element or layer, there are no intervening elements or layers present. As used herein, the term “and/or” includes any and all combinations of one or more of the associated listed items. Expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

As used herein, the singular form of the components may include a plural form unless the context clearly indicates otherwise. The drawings may be exaggerated to more clearly explain example embodiments.

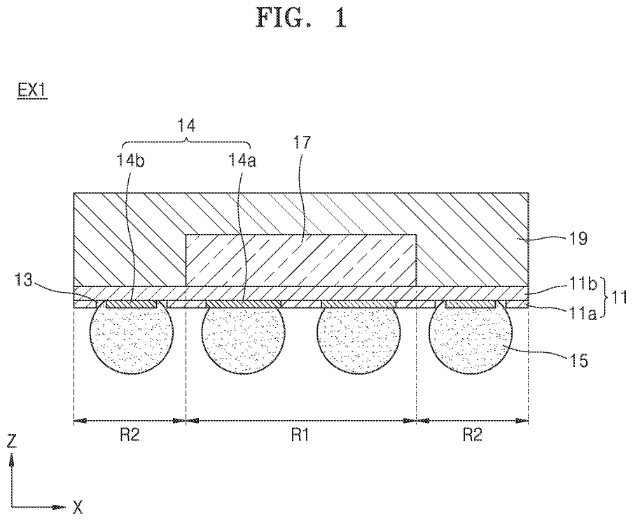

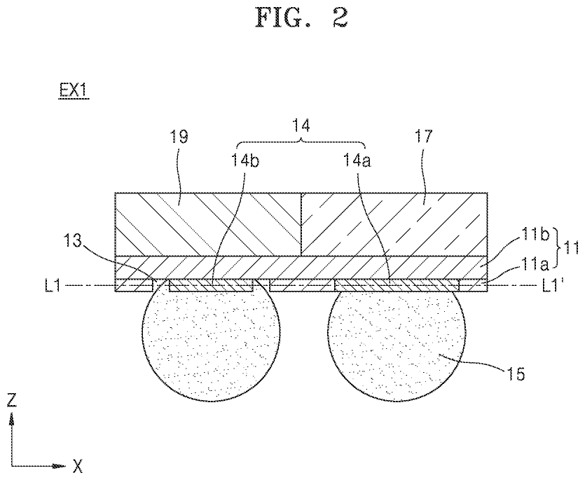

FIG. 1 is a cross-sectional view illustrating a semiconductor package according to example embodiments, and FIG. 2 is a partially enlarged view of the semiconductor package of FIG. 1.

Specifically, semiconductor package EX1 may include a wiring board 11, a chip 17, a molding layer 19, and solder balls 15. FIG. 1 is a cross-sectional view of a surface of the wiring board 11 in a first direction (X direction) and a third direction (Z direction). The third direction may be a direction perpendicular to the surface of the wiring board 11.

The wiring board 11 may be a printed circuit board (PCB). The wiring board 11 may include a base substrate layer 11b, a plurality of solder masks 11a formed on the lower surface of the base substrate layer 11b, and a plurality of solder ball lands 14. The solder ball lands 14 may be spaced apart in the first direction (X direction).

The base substrate layer 11b may include at least one of a prepreg resin, a thermosetting epoxy resin, a thermoplastic epoxy resin, and a resin containing a filler. A substrate wiring layer is formed in the base substrate layer 11b to be electrically connected to the chip 17 and the solder ball lands 14. The solder masks 11a may include photo sensitive resist (PSR).

The solder ball lands 14 may be formed of a metal layer. The solder ball lands 14 may be a single layer or a composite layer of a metal such as tin, silver, or copper. The solder ball lands 14 may include a plurality of solder mask defined (SMD) type solder ball lands 14a arranged entirely between the solder masks 11a. The SMD type solder ball lands 14a may be solder ball lands defined by the solder masks 11a.

As shown in FIGS. 1 and 2, the SMD type solder ball lands 14a may be formed to be in contact with both side surfaces of the solder masks 11a. The outer portions of the SMD type solder ball lands 14a may be surrounded by the solder masks 11a. The SMD type solder ball lands 14a may be arranged in the central area R1 of the wiring board 11. A plurality of SMD type solder ball lands 14a, for example, two SMD type solder ball lands 14a may be arranged to be separated from the central area R1 in the first direction (X direction).

The solder ball lands 14 may include a plurality of non-solder mask defined (NSMD) type solder ball lands 14b each arranged to define an open area 13 between the solder masks 11a and the NSMD type solder ball lands 14b that exposes the base substrate layer 11b. The NSMD type solder ball lands 14b may be solder ball lands which are not defined by the solder masks 11a. Widths of the NSMD type solder ball lands 14b may be smaller than those of the SMD type solder ball lands 14a.

As shown in FIGS. 1 and 2, the outer portions of the NSMD type solder ball lands 14b may be exposed by the open areas 13, respectively. The NSMD type solder ball lands 14b may be arranged in peripheral areas R2 of the wiring board 11. The peripheral areas R2 may be areas located at both sides of the central area R1.

In some example embodiments, the peripheral areas R2 may include corner areas of the wiring board 11. In some example embodiments, the NSMD type solder ball lands 14b may be dummy solder ball lands that are not electrically connected to the chip 17.

The chip 17 may be arranged on the wiring board 11. In some configurations, the chip 17 may be a single chip. The chip 17 may be electrically connected to the wiring board 11. The chip 17 may be connected to the wiring board 11 by bonding wires or bumps. The chip 17 may include an individual device. Individual devices may include various microelectronics devices, such as a metal-oxide-semiconductor field effect transistor (MOSFET) (e.g., a complementary metal-insulator-semiconductor (CMOS) transistor), an image sensor (e.g., a system large scale sensor (LSI) and a CMOS imaging sensor (CIS)), a micro-electro-mechanical system (MEMS), an active device, a passive device, and so on.

In some example embodiments, the chip 17 may be a logic chip, a power management integrated circuit (PMIC) chip, or a memory chip. In some example embodiments, the logic chip may be a memory controller chip, a central processing unit (CPU) chip, a graphics processing unit (GPU) chip, or an application processor (AP) chip.

In some example embodiments, the memory chip is a dynamic random access memory (DRAM) chip, a static random access memory (SRAM) chip, a flash memory chip, an electrically erasable and programmable read-only memory (EEPROM) chip, a phase-change random access memory (PRAM) chip, a magnetic random access memory (MRAM) chip, or a resistive random access memory (RRAM) chip.

The molding layer 19 may seal the chip 17 on the wiring board 11. The molding layer 19 may be formed on both side surfaces and the upper surface of the chip 17 to seal the chip 17. The molding layer 19 may be formed of, for example, a silicon-based material, a thermosetting material, a thermoplastic material, an ultra-violet (UV) treatment material, or the like. The molding layer 123 may be formed of a polymer such as resin, for example, an epoxy molding compound (EMC).

The solder balls 15 may be fused to the solder ball lands 14. The solder balls 15 may be attached to the solder ball lands 14. In some example embodiments, the solder balls attached to the NSMD type solder ball lands 14b-1 may be dummy solder balls that are not electrically connected to the chip 17.

The solder balls 15 may be formed of a metal or metal alloy of at least one of copper (Cu), aluminum (Al), nickel (Ni), silver (Ag), gold (Au), platinum (Pt), tin (Sn), lead (Pb), titanium (Ti), chromium (Cr), palladium (Pd), indium (In), and zinc (Zn).

The semiconductor package EX1 may have solder ball lands 14 including SMD type solder ball lands 14a and NSMD type solder ball lands 14b. The solder ball lands 14 of the semiconductor package EX1 may have a mixed arrangement structure of the SMD type solder ball lands 14a and the NSMD type solder ball lands 14b.

Accordingly, the semiconductor package EX1 may improve the bonding characteristics of the solder balls 15 and the solder ball lands 14, thereby exhibiting excellent strength and resilience when dropped. The semiconductor package EX1 may increase the fusion (or contact) area between the NSMD type solder ball lands 14b in peripheral areas R2 of the wiring board 11 and the solder balls 15. The bonding characteristics between the solder balls 15 and the solder ball lands 14b are improved and the solder balls 15 do not isolated during a drop test of the semiconductor package EX1. As a result, the semiconductor package EX1 may improve mechanical and electrical reliability of the solder balls 15.

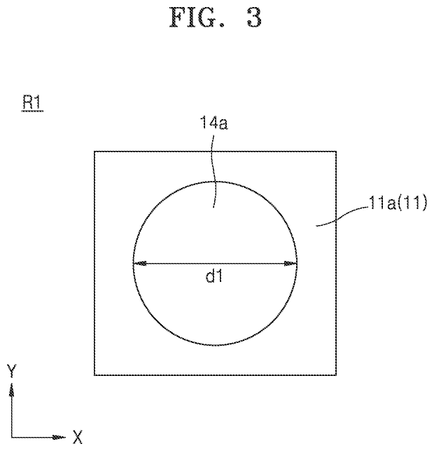

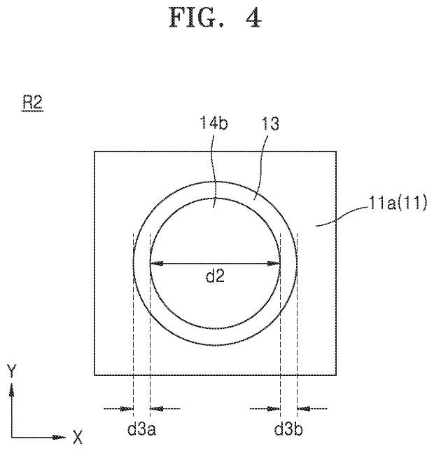

FIGS. 3 and 4 are plan views illustrating solder ball lands on a wiring board of the semiconductor packages of FIGS. 1 and 2.

Specifically, FIGS. 3 and 4 are plan views taken along line L1-L1′ of FIG. 2. FIGS. 3 and 4 are plan views of surfaces of the wiring board 11 in a first direction (X direction) and a second direction (Y direction), respectively.

FIG. 3 is a plan view illustrating the SMD type solder ball land 14a of FIGS. 1 and 2, and FIG. 4 is a plan view illustrating the NSMD type solder ball land 14b of FIGS. 1 and 2. FIGS. 3 and 4 will be briefly described with respect to the descriptions provided with reference to FIGS. 1 and 2.

As shown in FIG. 3, the wiring board 11 may have an X-Y plane extending in a first direction (X direction) and a second direction (Y direction). The SMD type solder ball lands 14a defined by the solder mask 11a may be arranged in the central area R1 of the wiring board 11. The outer portions of the SMD type solder ball lands 14a may be in contact with the solder mask 11a. In some example embodiments, the diameters d1 of the SMD type solder ball lands 14a may be about 100 micrometers to about 300 micrometers.

As shown in FIG. 4, the wiring board 11 may have an X-Y plane extending in a first direction (X direction) and a second direction (Y direction). The NSMD type solder ball lands 14b which are not defined by the solder mask 11a may be arranged in the peripheral areas R2 of the wiring board 11. In some example embodiments, the diameters d2 of the NSMD type solder ball lands 14b may be smaller than the diameters d1 of the SMD type solder ball lands 14a. In some example embodiments, the diameters d2 of the NSMD type solder ball lands 14b may be about 100 micrometers to about 300 micrometers.

An open area 13 may be located around each of the NSMD type solder ball lands 14b. The open area 13 may expose the outer portion of each of the NSMD type solder ball lands 14b. The outer portions of the NSMD type solder ball lands 14b may not contact the solder mask 11a. The left width d3a and the right width d3b of the open area 13 may be tens of micrometers, for example, about 10 micrometers to about 50 micrometers, respectively.

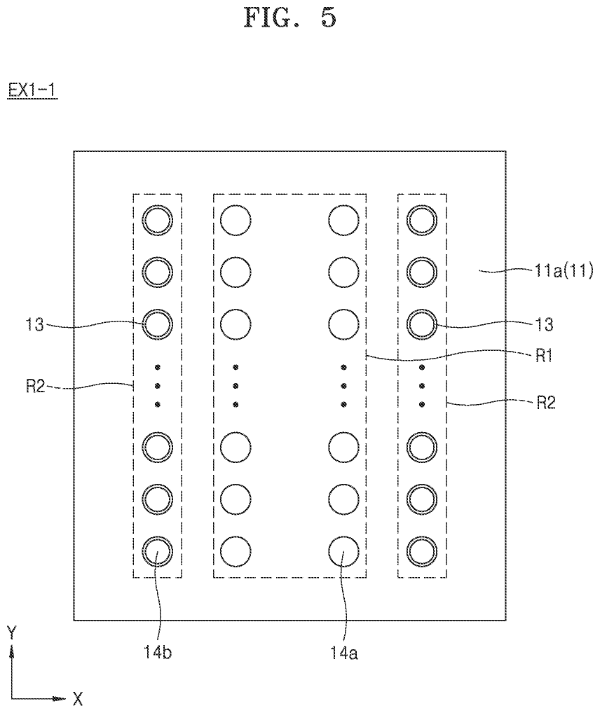

FIG. 5 is a plan view illustrating an arrangement of solder ball lands on a wiring board of a semiconductor package according to example embodiments.

Specifically, semiconductor package EX1-1 is a plan view illustrating solder ball lands 14 (of FIGS. 1 and 2) of the wiring board 11 shown in FIGS. 1 to 4, according to example embodiments. FIG. 5 will be briefly described with respect to the descriptions provided with reference to FIGS. 1 to 4.

The wiring board 11 may have an X-Y plane extending in a first direction (X direction) and a second direction (Y direction). The solder ball lands 14 of FIGS. 1 and 2 may include SMD type solder ball lands 14a and NSMD type solder ball lands 14b. The solder ball lands 14 may be spaced apart from each other in the first direction (X direction) and the second direction (Y direction).

The SMD type solder ball lands 14a may be located in the central area R1 of the wiring board 11 in a plan view. The SMD type solder ball lands 14a may be defined by the solder mask 11a. The SMD type solder ball lands 14a may be arranged in a plurality of columns spaced apart in the first direction (X direction) and extending in the second direction (Y direction) in the central area R1 of the X-Y plane of the wiring board 11. In some example embodiments, the SMD type solder ball lands 14a may be arranged in two columns, three columns, or more than three columns A plurality of SMD type solder ball lands 14a, for example, tens to hundreds of SMD type solder ball lands 14a may be arranged in a second direction (Y direction) in each column.

The NSMD type solder ball lands 14b may be located in peripheral areas R2 of the wiring board 11 in a plan view. The NSMD type solder ball lands 14b may not be defined by the solder mask 11a. An open area 13 may be located around each of the NSMD type solder ball lands 14b.

The NSMD type solder ball lands 14b may be located in peripheral areas R2 of both sides of the central area R1 in a plan view. A plurality of NSMD type solder ball lands 14b, for example, tens to hundreds of NSMD type solder ball lands 14b may be arranged in a second direction (Y direction) in one column.

In some example embodiments, unlike FIG. 5, NSMD type solder ball lands 14b may be positioned on only one of the peripheral areas R2 of the wiring board 11 in a plan view. The NSMD type solder ball lands 14b may be arranged in one column extending in the second direction (Y direction) in each of peripheral areas R2 of both sides of the central area R1.

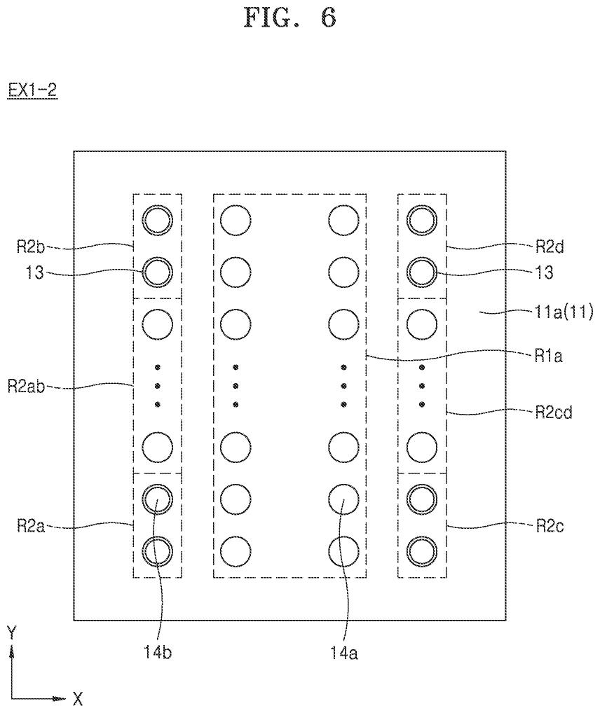

FIG. 6 is a plan view illustrating an arrangement of solder ball lands on a wiring board of a semiconductor package according to example embodiments.

Specifically, semiconductor package EX1-2 is a plan view illustrating solder ball lands 14 (of FIGS. 1 and 2) of the wiring board 11 shown in FIGS. 1 to 4, according to example embodiments. FIG. 6 will be briefly described with respect to the descriptions provided with reference to FIGS. 1 to 4.

The wiring board 11 may have an X-Y plane extending in a first direction (X direction) and a second direction (Y direction). The solder ball lands 14 of FIGS. 1 and 2 may include SMD type solder ball lands 14a and NSMD type solder ball lands 14b.

The SMD type solder ball lands 14a may be arranged in central area R1a, first peripheral area R2ab, and second peripheral area R2cd of the wiring board 11. The SMD type solder ball lands 14a may be defined by the solder mask 11a. The SMD type solder ball lands 14a may be arranged in a plurality of columns spaced apart in the first direction (X direction) and extending in the second direction (Y direction) in the first central area R1a of the X-Y plane of the wiring board 11.

In some example embodiments, the SMD type solder ball lands 14a formed in the first central area R1a may be arranged in two columns, three columns, or more than three columns. The SMD type solder ball lands 14a may be arranged in the first peripheral area R2ab and the second peripheral area R2cd located on both sides of the first central area R1a.

The NSMD type solder ball lands 14b may be located in first to fourth corner areas R2a, R2b, R2c, and R2d of the wiring board 11 in a plan view. The NSMD type solder ball lands 14b may not be defined by the solder mask 11a. An open area 13 may be located around each of the NSMD type solder ball lands 14b.

In some example embodiments, each of the first to fourth corner areas R2a, R2b, R2c, and R2d may include two NSMD type solder ball lands 14b. In some example embodiments, unlike FIG. 6, each of the first to fourth corner areas R2a, R2b, R2c, and R2d may include only one NSMD type solder ball land 14b adjacent to the edge of the wiring board 11. In some example embodiments, unlike FIG. 6, NSMD type solder ball lands 14b may be arranged in only one of the first to fourth corner areas R2a, R2b, R2c, and R2d.

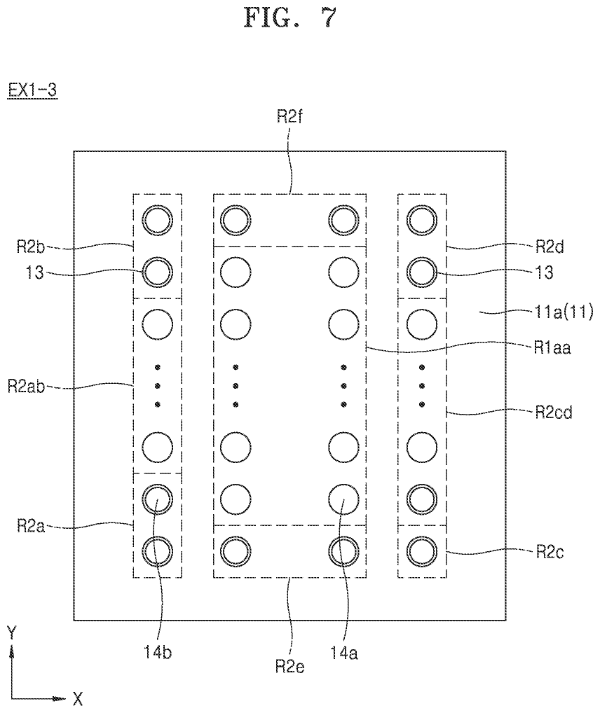

FIG. 7 is a plan view illustrating an arrangement of solder ball lands on a wiring board of a semiconductor package according to example embodiments.

Specifically, semiconductor package EX1-3 is a plan view illustrating solder ball lands 14 (of FIGS. 1 and 2) of the wiring board 11 shown in FIGS. 1 to 4, according to example embodiments. FIG. 7 will be briefly described with respect to the descriptions provided with reference to FIGS. 1 to 4.

The wiring board 11 may have an X-Y plane extending in a first direction (X direction) and a second direction (Y direction). The solder ball lands 14 of FIGS. 1 and 2 may include SMD type solder ball lands 14a and NSMD type solder ball lands 14b.

The SMD type solder ball lands 14a may be arranged in the central area R1aa, the first peripheral area R2ab, and the second peripheral area R2cd of the wiring board 11. The central area R1aa may be a partial area of the central area R1a of FIG. 6. The SMD type solder ball lands 14a may be defined by the solder mask 11a. The SMD type solder ball lands 14a may be arranged in a plurality of columns spaced apart in the first direction (X direction) and extending in the second direction (Y direction) in the first central area R1aa of the X-Y plane of the wiring board 11.

In some example embodiments, the SMD type solder ball lands 14a formed in the first central area R1aa may be arranged in two columns, three columns, or more than three columns. The SMD type solder ball lands 14a may be arranged in the first peripheral area R2ab and the second peripheral area R2ac located on both sides of the first central area R1aa.

The NSMD type solder ball lands 14b may be located in first to fourth corner areas R2a, R2b, R2c, and R2d of the wiring board 11 in a plan view. The NSMD type solder ball lands 14b may be arranged in the third peripheral area R2e and the fourth peripheral area R2f of the lower and upper portions of the central area R1aa in a plan view. The NSMD type solder ball lands 14b may not be defined by the solder mask 11a. An open area 13 may be located around each of the NSMD type solder ball lands 14b.

In some example embodiments, NSMD type solder ball lands 14b may be arranged in only one of the third peripheral area R2e and the fourth peripheral area R2f, unlike FIG. 7. In some example embodiments, each of the first to fourth corner areas R2a, R2b, R2c, and R2d may include two NSMD type solder ball lands 14b.

In some example embodiments, unlike FIG. 7, each of the first to fourth corner areas R2a, R2b, R2c, and R2d may include only one NSMD type solder ball land 14b adjacent to the edge of the wiring board 11. In some example embodiments, unlike FIG. 7, NSMD type solder ball lands 14b may be arranged in only one of the first to fourth corner areas R2a, R2b, R2c, and R2d.

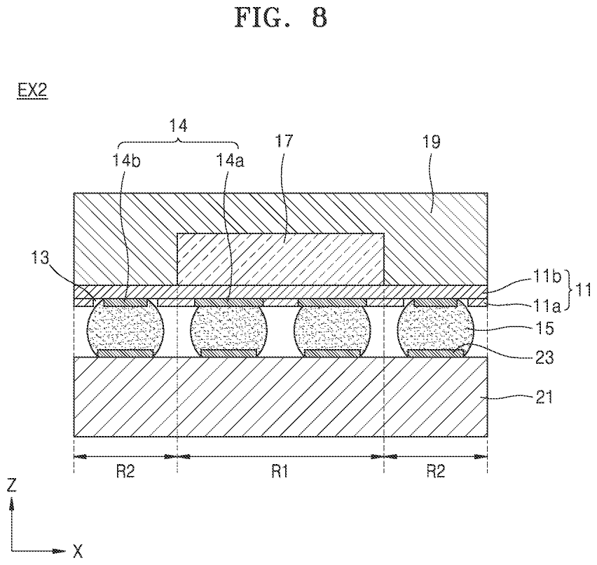

FIG. 8 is a cross-sectional view illustrating a semiconductor package according to example embodiments.

Specifically, semiconductor package EX2 may be substantially similar to the semiconductor package EX1 of FIGS. 1 and 2, except that the semiconductor package EX2 further includes a board substrate 21 having a plurality of conductive pads 23 fused with the solder balls 15. FIG. 8 will be briefly described with respect to the descriptions provided with reference to FIGS. 1 and 2.

The semiconductor package EX2 may include a wiring board 11, a chip 17, a molding layer 19, solder balls 15, and a board substrate 21. The chip 17 may be arranged on the wiring board 11 and electrically connected to the wiring board 11. The molding layer 19 may seal the chip 17 on the wiring board 11.

Solder ball lands 14 are arranged on the lower surface of the wiring board 11. The solder ball lands 14 may include SMD type solder ball lands 14a and NSMD type solder ball lands 14b. The SMD type solder ball lands 14a may be arranged in the central area R1 of the wiring board 11. The NSMD type solder ball lands 14b may be arranged in peripheral areas R2 of the wiring board 11. The solder balls 15 may be arranged on the lower surface of the wiring board 11 and may be fused with the solder ball lands 14.

The board substrate 21 may include a plurality of conductive pads 23 arranged on an upper surface thereof. The conductive pads 23 of the board substrate 21 may be fused to the solder balls 15. Like the wiring board 11, the board substrate 21 may include a central area R1 and peripheral areas R2.

The solder ball lands 14 of the semiconductor package EX2 may have a mixed arrangement structure of the SMD type solder ball lands 14a and the NSMD type solder ball lands 14b. The semiconductor package EX2 may increase the fusion (or contact) area between the NSMD type solder ball lands 14b in peripheral areas R2 of the wiring board 11 and the solder balls 15. Accordingly, the semiconductor package EX2 may improve the bonding characteristics of the solder balls 15 and the solder ball lands 14, thereby exhibiting excellent strength and resilience when dropped. In other words, the solder balls 15 do not isolated during a drop test of the semiconductor package EX2. As a result, the semiconductor package EX2 may improve mechanical and electrical reliability of the solder balls 15.

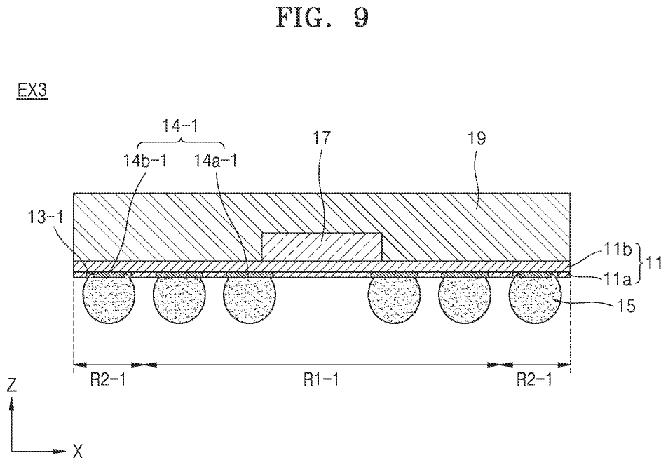

FIG. 9 is a cross-sectional view illustrating a semiconductor package according to example embodiments.

Specifically, semiconductor package EX3 may be substantially similar to the semiconductor package EX1 of FIGS. 1 and 2, except that the configurations of the solder ball lands 14-1 in the central area R1-1 of the wiring board 11 in the semiconductor package EX3 are different from those of the semiconductor package EX1. FIG. 9 will be briefly described with respect to the descriptions provided with reference to FIGS. 1 and 2.

The semiconductor package EX3 may include a wiring board 11, a chip 17, a molding layer 19, and solder balls 15. FIG. 9 is a cross-sectional view of a surface of the wiring board 11 in a first direction (X direction) and a third direction (Z direction). The third direction may be a direction perpendicular to the surface of the wiring board 11.

The wiring board 11 may be a printed circuit board (PCB). The wiring board 11 may include a base substrate layer 11b, a plurality of solder masks 11a formed on the lower surface of the base substrate layer 11b, and a plurality of solder ball lands 14-1. The solder ball lands 14-1 may be arranged to be spaced apart in the first direction (X direction). The solder ball lands 14-1 may be formed of a metal layer. The solder ball lands 14-1 may be a single layer or a composite layer of a metal such as tin, silver, or copper.

The solder ball lands 14-1 may include a plurality of solder mask defined (SMD) type solder ball lands 14a-1 arranged entirely between the solder masks 11a. The SMD type solder ball lands 14a-1 may be solder ball lands defined by the solder masks 11a. The SMD type solder ball lands 14a-1 may correspond to the SMD type solder ball lands 14a of FIGS. 1 to 4.

The SMD type solder ball lands 14a-1 may be arranged in the central area R1-1 of the wiring board 11. A plurality of SMD type solder ball lands 14a-1, for example, four SMD type solder ball lands 14a-1 may be arranged to be separated from the central area R1-1 in the first direction (X direction). Two SMD type solder ball lands 14a-1 may be arranged on both sides of the chip 17 in the first direction (X direction) with respect to the chip 17.

In some example embodiments, three SMD type solder ball lands 14a-1 may be arranged on both sides of the chip 17 in the first direction (X direction) with respect to the chip 17. The SMD type solder ball lands 14a-1 may be arranged in various forms in the central area R1-1 of the wiring board 11 according to the function or performance of the semiconductor package EX3.

The solder ball lands 14-1 may include a plurality of NSMD type solder ball lands 14b-1 each arranged to define an open area 13-1 between the solder masks 11a and the NSMD type solder ball lands 14b-1 that exposes the base substrate layer 11b. The SMD type solder ball lands 14b-1 may be solder ball lands which are not defined by the solder masks 11a. Widths of the NSMD type solder ball lands 14b-1 may be smaller than those of the SMD type solder ball lands 14a. The NSMD type solder ball lands 14b-1 may correspond to the NSMD type solder ball lands 14b of FIGS. 1 to 4.

The NSMD type solder ball lands 14b-1 may be arranged in peripheral areas R2-1 of the wiring board 11. The peripheral areas R2-1 may be areas located at both sides of the central area R1-1. In some example embodiments, the peripheral areas R2-1 may include corner areas of the wiring board 11. In some example embodiments, the NSMD type solder ball lands 14b-1 may be dummy solder ball lands that are not electrically connected to the chip 17.

The chip 17 may be arranged on the wiring board 11. The chip 17 may be electrically connected to the wiring board 11. The chip 17 may be connected to the wiring board 11 by bonding wires or bumps. The molding layer 19 may seal the chip 17 on the wiring board 11. The solder balls 15 may be fused to the solder ball lands 14-1. The solder balls 15 may be attached to the solder ball lands 14-1. In some example embodiments, the solder balls attached to the NSMD type solder ball lands 14b-1 may be dummy solder balls that are not electrically connected to the chip 17.

The solder ball lands 14-1 of the semiconductor package EX3 may have a mixed arrangement structure of the SMD type solder ball lands 14a and the NSMD type solder ball lands 14b. The semiconductor package EX3 may increase the fusion (or contact) area between the NSMD type solder ball lands 14b in peripheral areas R2-1 of the wiring board 11 and the solder balls 15. Accordingly, the semiconductor package EX3 may improve the bonding characteristics of the solder balls 15 and the solder ball lands 14-1, thereby exhibiting excellent strength and resilience when dropped. In other words, the solder balls 15 do not isolated during a drop test of the semiconductor package EX3. As a result, the semiconductor package EX3 may improve mechanical and electrical reliability of the solder balls 15.

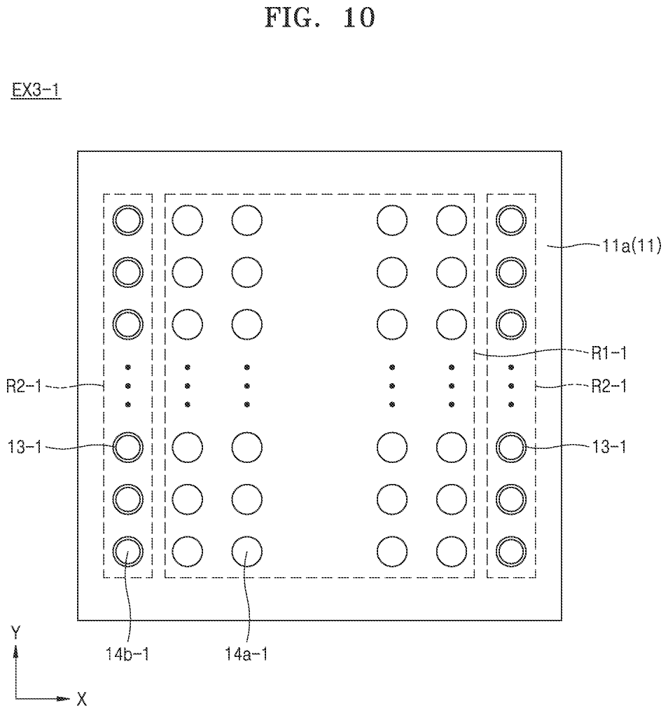

FIG. 10 is a plan view illustrating an arrangement of solder ball lands on a wiring board of a semiconductor package according to example embodiments.

Specifically, semiconductor package EX3-1 of FIG. 10 is a plan view illustrating solder ball lands 14-1 of the wiring board 11 shown in FIG. 9, according to example embodiments. FIG. 10 will be briefly described with respect to the descriptions provided with reference to FIG. 9.

The wiring board 11 may have an X-Y plane extending in a first direction (X direction) and a second direction (Y direction). The solder ball lands 14-1 of FIG. 9 may include SMD type solder ball lands 14a-1 and NSMD type solder ball lands 14b-1.

The SMD type solder ball lands 14a-1 may be located in the central area R1-1 of the wiring board 11 in a plan view. The SMD type solder ball lands 14a-1 may be defined by the solder mask 11a. The SMD type solder ball lands 14a-1 may be arranged in a plurality of columns spaced apart in the first direction (X direction) and extending in the second direction (Y direction) in the central area R1-1 of the X-Y plane of the wiring board 11.

In some example embodiments, the SMD type solder ball lands 14a-1 may be arranged in four columns. In some example embodiments, SMD type solder ball lands 14a-1 may be arranged in two columns, respectively, on the left and right sides in the first direction (X direction). A plurality of SMD type solder ball lands 14a-1, for example, tens to hundreds of SMD type solder ball lands 14a-1 may be arranged in a second direction (Y direction) in one column.

In some example embodiments, SMD type solder ball lands 14a-1 may be arranged in six columns in the first direction (X direction), unlike FIG. 10. In some example embodiments, SMD type solder ball lands 14a-1 may be arranged in three columns, respectively, on the left and right sides in the first direction (X direction).

The NSMD type solder ball lands 14b-1 may be located in peripheral areas R2-1 of the wiring board 11 in a plan view. The NSMD type solder ball lands 14b-1 may not be defined by the solder mask 11a. An open area 13-1 may be located around each of the NSMD type solder ball lands 14b-1. The NSMD type solder ball lands 14b-1 may be located in peripheral areas R2-1 of both sides of the central area R1-1 in a plan view.

In some example embodiments, unlike FIG. 10, NSMD type solder ball lands 14b-1 may be positioned on only one of the peripheral areas R2-1 of the wiring board 11 in a plan view. The NSMD type solder ball lands 14b-1 may be arranged in one column extending in the second direction (Y direction) in each of peripheral areas R2-1 of both sides of the central area R1-1. A plurality of NSMD type solder ball lands 14b-1, for example, tens to hundreds of NSMD type solder ball lands 14b-1 may be arranged in a second direction (Y direction) in one column.

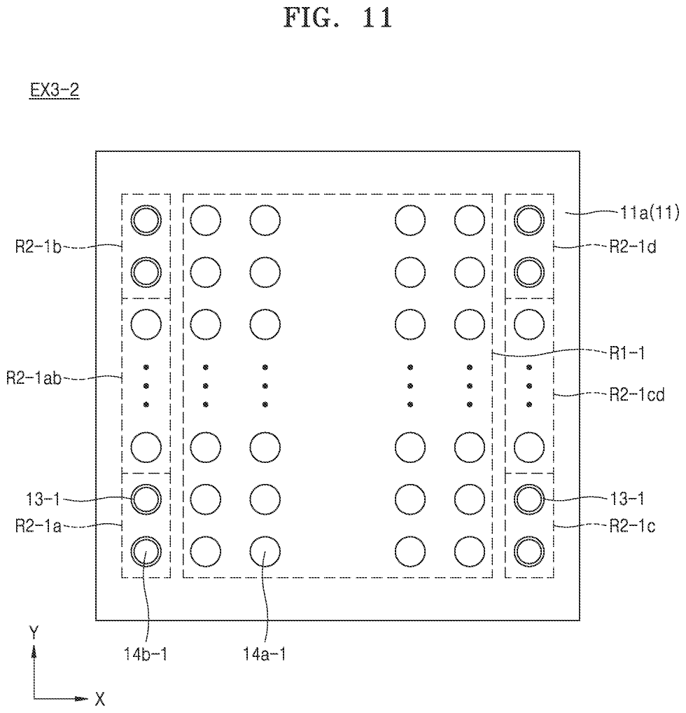

FIG. 11 is a plan view illustrating an arrangement of solder ball lands on a wiring board of a semiconductor package according to example embodiments.

Specifically, the semiconductor package EX3-2 of FIG. 11 is a plan view illustrating solder ball lands 14-1 of the wiring board 11 shown in FIG. 9, according to example embodiments. FIG. 11 will be briefly described with respect to the descriptions provided with reference to FIG. 9.

The wiring board 11 may have an X-Y plane extending in a first direction (X direction) and a second direction (Y direction). The solder ball lands 14-1 of FIG. 9 may include SMD type solder ball lands 14a-1 and NSMD type solder ball lands 14b-1.

The SMD-type solder ball lands 14a-1 may be arranged in a central area R1-1, a first peripheral area R2-1ab, and a second peripheral area R2-1cd of the wiring board 11. The SMD type solder ball lands 14a-1 may be defined by the solder mask 11a.

The SMD type solder ball lands 14a-1 may be arranged in a plurality of columns spaced apart in the first direction (X direction) and extending in the second direction (Y direction) in the first central area R1-1 of the X-Y plane of the wiring board 11. The SMD type solder ball lands 14a-1 may be arranged in the first peripheral area R2-1ab and the second peripheral area R2-1cd located on both sides of the first central area R1-1.

In some example embodiments, the SMD type solder ball lands 14a-1 formed in the first central area R1-1 may be arranged in four columns. In some example embodiments, SMD type solder ball lands 14a-1 may be arranged in two columns, respectively, on the left and right sides in the first direction (X direction).

In some example embodiments, SMD type solder ball lands 14a-1 may be arranged in six columns in the first direction (X direction), unlike FIG. 10. In some example embodiments, SMD type solder ball lands 14a-1 may be arranged in three columns, respectively, on the left and right sides in the first direction (X direction).

The NSMD type solder ball lands 14b-1 may be located in first to fourth corner areas R2-1a, R2-1b, R2-1c, and R2-1d of the wiring board 11 in a plan view. The NSMD type solder ball lands 14b-1 may not be defined by the solder mask 11a. An open area 13-1 may be located around each of the NSMD type solder ball lands 14b-1.

In some example embodiments, each of the first to fourth corner areas R2-1a, R2-1b, R2-1c, and R2-1d may include two NSMD type solder ball lands 14b-1. In some example embodiments, unlike FIG. 11, each of the first to fourth corner areas R2-1a, R2-1b, R2-1c, and R2-1d may include only one NSMD-type solder ball land 14b-1 adjacent to the edge of the wiring board 11. In some example embodiments, unlike FIG. 11, NSMD type solder ball lands 14b-1 may be arranged in only one of the first to fourth corner areas R2-1a, R2-1b, R2-1c, and R2-1d.

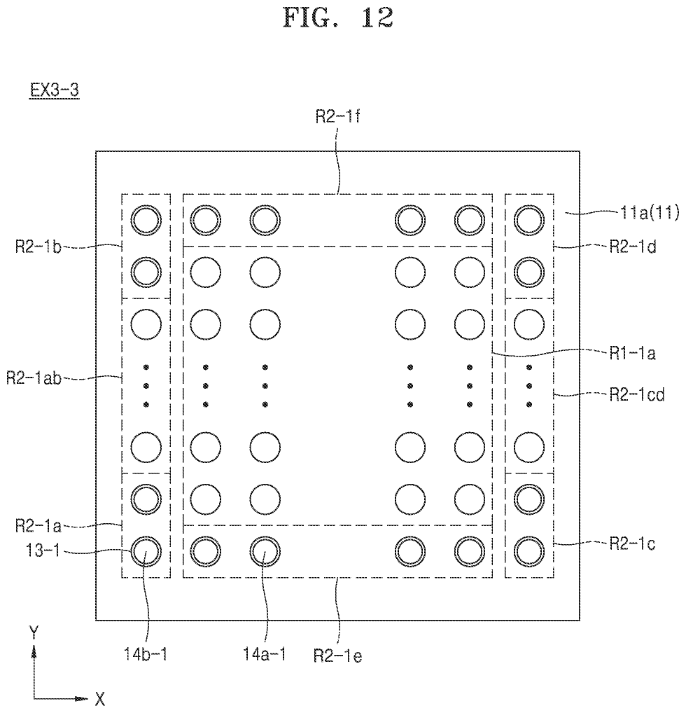

FIG. 12 is a plan view illustrating an arrangement of solder ball lands on a wiring board of a semiconductor package according to example embodiments.

Specifically, semiconductor package EX3-3 of FIG. 12 is a plan view illustrating solder ball lands 14-1 of the wiring board 11 shown in FIG. 9, according to example embodiments. FIG. 12 will be briefly described with respect to the descriptions provided with reference to FIG. 9.

The wiring board 11 may have an X-Y plane extending in a first direction (X direction) and a second direction (Y direction). The solder ball lands 14-1 of FIG. 9 may include SMD type solder ball lands 14a-1 and NSMD type solder ball lands 14b-1.

The SMD-type solder ball lands 14a-1 may be arranged in a central area R1-1a, a first peripheral area R2-1ab, and a second peripheral area R2-1cd of the wiring board 11. The central area R1-1a may be a partial area of the central area R1-1 of FIG. 6. The SMD type solder ball lands 14a-1 may be defined by the solder mask 11a. The SMD type solder ball lands 14a-1 may be arranged in a plurality of columns spaced apart in the first direction (X direction) and extending in the second direction (Y direction) in the first central area R1-1a of the X-Y plane of the wiring board 11. The SMD type solder ball lands 14a-1 may be arranged in the first peripheral area R2-1ab and the second peripheral area R2-1cd located on both sides of the first central area R1-1a.

In some example embodiments, the SMD type solder ball lands 14a-1 formed in the first central area R1-1a may be arranged in four columns. In some example embodiments, SMD type solder ball lands 14a-1 may be arranged in two columns, respectively, on the left and right sides in the first direction (X direction).

In some example embodiments, SMD type solder ball lands 14a-1 may be arranged in six columns in the first direction (X direction), unlike FIG. 12. In some example embodiments, SMD type solder ball lands 14a-1 may be arranged in three columns, respectively, on the left and right sides in the first direction (X direction).

The NSMD type solder ball lands 14b-1 may be located in first to fourth corner areas R2-1a, R2-1b, R2-1c, and R2-1d of the wiring board 11 in a plan view. The NSMD type solder ball lands 14b may be arranged in the third peripheral area R2-le and the fourth peripheral area R2-1f of the lower and upper portions of the central area R1-1a in a plan view. The NSMD type solder ball lands 14b-1 may not be defined by the solder mask 11a. An open area 13-1 may be located around each of the NSMD type solder ball lands 14b-1.

In some example embodiments, NSMD type solder ball lands 14b-1 may be arranged in only one of the third peripheral area R2-le and the fourth peripheral area R2-1f, unlike FIG. 12. In some example embodiments, each of the first to fourth corner areas R2-1a, R2-1b, R2-1c, and R2-1d may include two NSMD type solder ball lands 14b-1.

In some example embodiments, unlike FIG. 12, each of the first to fourth corner areas R2-1a, R2-1b, R2-1c, and R2-1d may include only one NSMD-type solder ball land 14b-1 adjacent to the edge of the wiring board 11. In some example embodiments, unlike FIG. 12, NSMD type solder ball lands 14b-1 may be arranged in only one of the first to fourth corner areas R2-1a, R2-1b, R2-1c, and R2-1d.

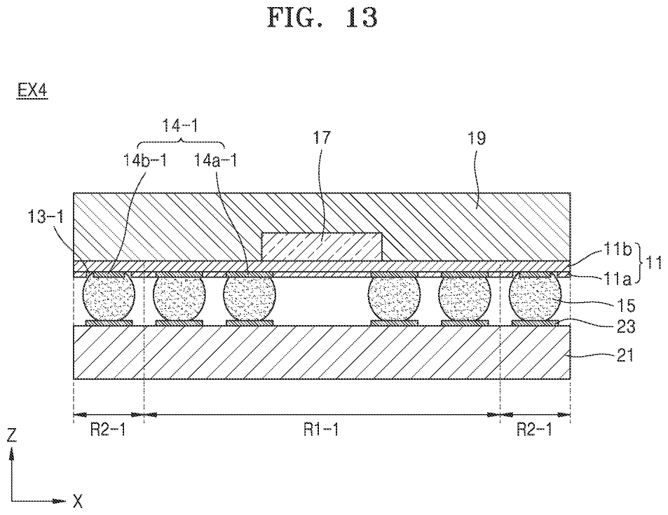

FIG. 13 is a cross-sectional view illustrating a semiconductor package according to example embodiments.

Specifically, semiconductor package EX4 may be substantially similar to the semiconductor package EX3 of FIG. 9, except that the semiconductor package EX2 further includes a board substrate 21 having a plurality of conductive pads 23 fused with the solder balls 15. FIG. 13 will be briefly described with respect to the descriptions provided with reference to FIG. 9.

The semiconductor package EX4 may include a wiring board 11, a chip 17, a molding layer 19, solder balls 15, and a board substrate 21. The chip 17 may be arranged on the wiring board 11 and electrically connected to the wiring board 11. The molding layer 19 may seal the chip 17 on the wiring board 11.

Solder ball lands 14-1 are arranged on the lower surface of the wiring board 11. The solder ball lands 14-1 may include SMD type solder ball lands 14a-1 and NSMD type solder ball lands 14b-1. The SMD type solder ball lands 14a-1 may be arranged in the central area R1-1 of the wiring board 11. The NSMD type solder ball lands 14b-1 may be arranged in peripheral areas R2-1 of the wiring board 11. The solder balls 15 may be arranged on the lower surface of the wiring board 11 and may be fused with the solder ball lands 14-1.

The board substrate 21 may include a plurality of conductive pads 23 arranged on an upper surface thereof. The conductive pads 23 of the board substrate 21 may be fused to the solder balls 15. Like the wiring board 11, the board substrate 21 may include a central area R1-1 and peripheral areas R2-1.

The solder ball lands 14-1 of the semiconductor package EX4 may have a mixed arrangement structure of the SMD type solder ball lands 14a-1 and the NSMD type solder ball lands 14b-1. The semiconductor package EX4 may increase the fusion (or contact) area between the NSMD type solder ball lands 14b-1 in peripheral areas R2-1 of the wiring board 11 and the solder balls 15. Accordingly, the semiconductor package EX4 may improve the bonding characteristics of the solder balls 15 and the solder ball lands 14-1, thereby exhibiting excellent strength and resilience when dropped. In other words, the solder balls 15 do not isolated during a drop test of the semiconductor package EX4. As a result, the semiconductor package EX4 may improve mechanical and electrical reliability of the solder balls 15.

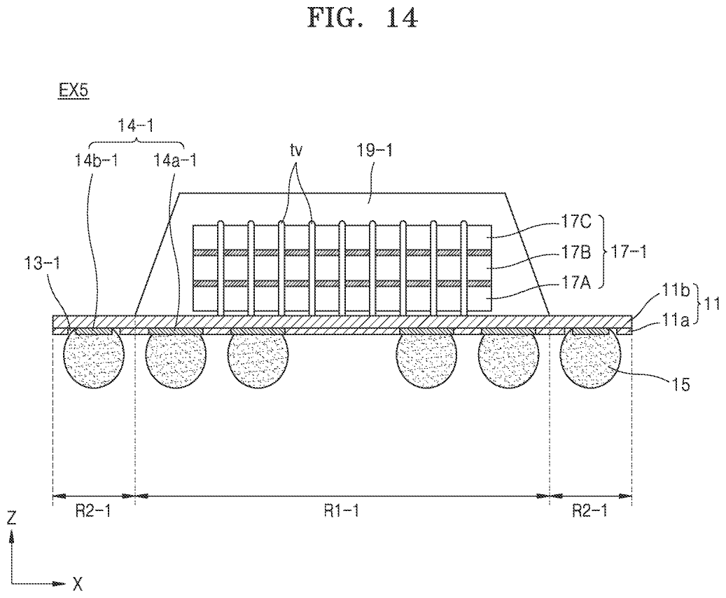

FIG. 14 is a cross-sectional view illustrating a semiconductor package according to example embodiments.

Specifically, semiconductor package EX5 may be substantially similar to the semiconductor package EX3 of FIG. 9 except that a stacked chip 17-1 is included. FIG. 14 will be briefly described with respect to the descriptions provided with reference to FIG. 9.

The semiconductor package EX5 may include a wiring board 11, a stacked chip 17-1, a molding layer 19-1, solder balls 15, and a board substrate 21. The stacked chip 17-1 may be arranged on the wiring board 11 and electrically connected to the wiring board 11.

The stacked chip 17-1 may include a plurality of chips 17A, 17B, and 17C mounted on the wiring board 11. The chips 17A, 17B, and 17C may be electrically connected to the wiring board 11 via through via electrodes tv. The through via electrodes TV may be through silicon via electrodes. The molding layer 19-1 may seal the stacked chip 17-1 on the wiring board 11.

Solder ball lands 14-1 are arranged on the lower surface of the wiring board 11. The solder ball lands 14-1 may include SMD type solder ball lands 14a-1 and NSMD type solder ball lands 14b-1. The SMD type solder ball lands 14a-1 may be arranged in the central area R1-1 of the wiring board 11. The NSMD type solder ball lands 14b-1 may be arranged in peripheral areas R2-1 of the wiring board 11. The solder balls 15 may be arranged on the lower surface of the wiring board 11 and may be fused with the solder ball lands 14-1.

The solder ball lands 14-1 of the semiconductor package EX5 may have a mixed arrangement structure of the SMD type solder ball lands 14a-1 and the NSMD type solder ball lands 14b-1. The semiconductor package EX5 may increase the fusion (or contact) area between the NSMD type solder ball lands 14b-1 in peripheral areas R2-1 of the wiring board 11 and the solder balls 15. Accordingly, the semiconductor package EX5 may improve the bonding characteristics of the solder balls 15 and the solder ball lands 14-1, thereby exhibiting excellent strength and resilience when dropped. In other words, the solder balls 15 do not isolated during a drop test of the semiconductor package EX5. As a result, the semiconductor package EX5 may improve mechanical and electrical reliability of the solder balls 15.

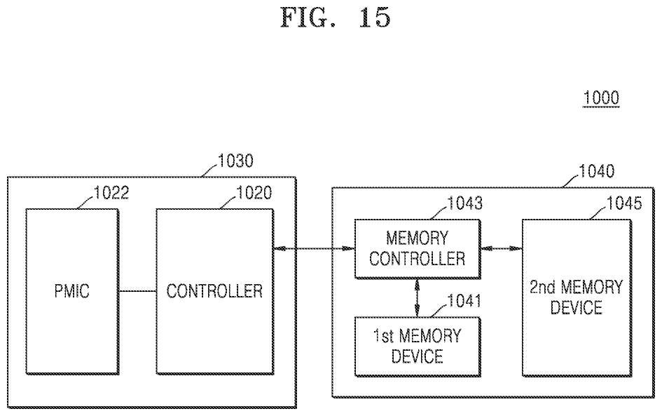

FIG. 15 is a block diagram illustrating a configuration of a semiconductor package according to example embodiments.

Specifically, semiconductor package 1000 may correspond to any one of the semiconductor packages EX1 to EX5 of example embodiments. The semiconductor package 1000 may include various hardware components, including a controller device (or a controller chip) 1020, a first memory device (or a first memory chip) 1041, a second memory device (or a second memory chip) 1045, and a memory controller 1043. The semiconductor package 1000 may further include a power management integrated circuit (PMIC) chip 1022 that supplies a current of an operating voltage to each of the controller chip 1020, the first memory device 1041, the second memory device 1045, and the memory controller 1043. The operating voltages applied to the respective components may be designed to be the same or different from each other.

A lower package 1030 including the controller device 1020 and the power management chip 1022 may include any one of the semiconductor packages EX1 to EX8 described above. An upper package 1040 including the first memory device 1041, the second memory device 1045, and the memory controller 1043 may include any one of the semiconductor packages EX1 to EX8 described above.

The semiconductor package 1000 may be implemented to be included in a personal computer (PC) or a mobile device. Mobile devices may be implemented as laptop computers, mobile phones, smartphones, tablet PCs, personal digital assistants (PDAs), enterprise digital assistants (EDAs), digital still cameras, digital video cameras, portable multimedia players (PMPs), personal navigation devices or portable navigation devices (PNDs), handheld game consoles, mobile internet devices (MIDs), wearable computers, Internet of things (IoT) devices, Internet of everything (IoE) devices, or a drone.

The controller device 1020 may control operations of each of the first memory device 1041, the second memory device 1045, and the memory controller 1043. For example, the controller device 1020 may be implemented as an integrated circuit (IC), a system on chip (SoC), an application processor (AP), a mobile AP, a chipset, or a set of chips. The controller device 1020 may include a central processing unit (CPU), a graphics processing unit (GPU), and/or a modem. In some example embodiments, the controller device 1020 may perform a function of a modem and a function of an AP.

The memory controller 1043 may control the second memory device 1045 under the control of the controller device 1020. The first memory device 1041 may be implemented as a volatile memory device. A volatile memory device may be implemented as random access memory (RAM), dynamic RAM (DRAM), or static RAM (SRAM), but is not limited thereto. The second memory device 1045 may be implemented as a storage memory device. The storage memory device may be implemented as a nonvolatile memory device.

The storage memory device may be implemented as a flash-based memory device, but is not limited thereto. The second memory device 1045 may be implemented as a NAND-type flash memory device. The NAND-type flash memory device may include a two-dimensional (2D) memory cell array or a three-dimensional (3D) memory cell array. The two-dimensional memory cell array or the three-dimensional memory cell array may include a plurality of memory cells, and each of the plurality of memory cells may store one-bit information or two-bit or more information.

When the second memory device 1045 is implemented as a flash-based memory device, the memory controller 1043 may use (or support) a multimedia card (MMC) interface, an embedded MMC interface, or a universal flash storage (UFS) interface, but is not thereto.

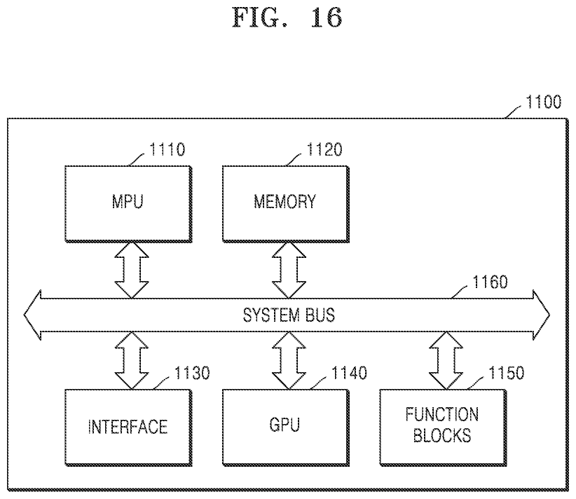

FIG. 16 is a block diagram schematically illustrating a configuration of a semiconductor package according to example embodiments.

Specifically, semiconductor package 1100 may include various hardware components, including a micro processing unit (MPU) 1110, a memory 1120, an interface 1130, a graphic processing unit 1140, function blocks 1150, and a system bus 1160 connecting the MPU 1110, the memory 1120, the interface 1130, the GPU 1140, and the functional blocks 1150 with each other. The semiconductor package 1100 may include both the MPU 1110 and the GPU 1140, or only one of the MPU 1110 and the GPU 1140.

The MPU 1110 may include a core and an L2 cache. For example, the MPU 1110 may include a multi-core. Each core of the multi-core may have the same or different performance. In addition, each core of the multi-core may be activated at the same time or may have a different time point at which it is activated. The memory 1120 may store results and the like processed by the function blocks 1150 under the control of the MPU 1110. For example, when data stored in an L2 cache of the MPU 1110 is flushed, the MPU 1110 may have the data be stored in the memory 1120. The interface 1130 may perform interfacing with external devices. For example, the interface 1130 may perform interfacing with a camera, an LCD, a speaker, and the like.

The GPU 1140 may perform graphic functions. For example, the GPU 1140 may perform a video codec or process a 3D graphic. The function blocks 1150 may perform various functions. For example, when the semiconductor package 1100 is an AP used in a mobile device, some of the function blocks 1150 may perform a communication function.

The semiconductor package 1100 may include any one of the semiconductor packages EX1 to EX5 discussed above. The MPU 1110 and/or the GPU 1140 may include any one of the semiconductor packages EX1 to EX8 discussed above. The memory 1120 may include any one of the semiconductor packages EX1 to EX8 discussed above. The interface 1130 and the function blocks 1150 may include any one of the semiconductor packages EX1 to EX8 discussed above.

While aspects of example embodiments have been particularly shown and described, it will be understood that various changes in form and details may be made therein without departing from the spirit and scope of the following claims.

What is claimed is:

1. A semiconductor package comprising:
a wiring board comprising a base substrate layer, and solder masks and a plurality of solder ball lands provided on the base substrate layer;
a chip provided on and electrically connected to the wiring board;
a molding layer provided on the chip and the wiring board; and
a plurality of solder balls arranged on a lower surface of the wiring board and fused with the plurality of solder ball lands,
wherein the plurality of solder ball lands comprise a plurality of solder mask defined (SMD) type solder ball lands having side surfaces in contact with the solder masks, and a plurality of non-solder mask defined (NSMD) type solder ball lands that are separated from the solder masks to define an open area that exposes the base substrate layer.

2. The semiconductor package of claim 1, wherein the plurality of SMD type solder ball lands are wider than the plurality of NSMD type solder ball lands.

3. The semiconductor package of claim 1, wherein the plurality of NSMD type solder ball lands are electrically isolated from the chip.

4. The semiconductor package of claim 1, wherein the plurality of SMD type solder ball lands are located in a central area of the wiring board in a plan view, and the plurality of NSMD type solder ball lands are located in corner areas of the wiring board in the plan view.

5. The semiconductor package of claim 1, wherein the plurality of SMD type solder ball lands are located in a central area of the wiring board in a plan view, and the plurality of NSMD type solder ball lands are located in peripheral areas of the wiring board in the plan view.

6. The semiconductor package of claim 1, wherein the plurality of NSMD type solder ball lands are located in peripheral areas of both sides of a central area in a plan view in which the plurality of SMD type solder ball lands are located.

7. The semiconductor package of claim 1, wherein the plurality of SMD type solder ball lands are arranged in a central area of the wiring board in a plan view, and the plurality of NSMD type solder ball lands are arranged on upper and lower peripheral areas of the central area in the plan view, and on corner areas of the wiring board in the plan view.

8. The semiconductor package of claim 1, wherein the chip comprises a single chip or a stacked chip.

9. A semiconductor package comprising:
a wiring board comprising a base substrate layer, and solder masks and a plurality of solder ball lands provided on the base substrate layer;
a chip provided on and electrically connected to the wiring board;
a molding layer provided on the chip and the wiring board; and
a plurality of solder balls arranged on a lower surface of the wiring board and fused with the plurality of solder ball lands,
wherein the plurality of solder ball lands comprise a plurality of solder mask-defined (SMD) type solder ball lands of which outer portions are in contact with the solder masks, and a plurality of non-solder mask defined (NSMD) type solder ball lands of which outer portions are exposed by open areas between the plurality of NSMD type solder ball lands and the solder masks.

10. The semiconductor package of claim 9, wherein the plurality of SMD type solder ball lands are wider than the plurality of NSMD type solder ball lands.

11. The semiconductor package of claim 9, wherein the plurality of NSMD type solder ball lands are electrically isolated from the chip.

12. The semiconductor package of claim 9, wherein the wiring board extends in an X direction and a Y direction,
wherein the plurality of NSMD type solder ball lands are arranged in a first column and a second column that both extend in the Y direction, and
wherein the plurality of SMD type solder ball lands are arranged in a plurality of columns spaced apart in the X direction and extending in the Y direction in a central area of the wiring board between the first column and the second column.

13. The semiconductor package of claim 9, wherein the wiring board extends in an X direction and a Y direction,
wherein the plurality of SMD type solder ball lands are arranged in a plurality of columns extending in the Y direction in a central area of the wiring board, and
wherein the plurality of NSMD type solder ball lands are arranged in corner areas of the wiring board.

14. The semiconductor package of claim 9, wherein the wiring board extends in an X direction and a Y direction,
wherein the plurality of SMD type solder ball lands are arranged in a plurality of columns spaced apart in the X direction and extending in the Y direction in a central area of the wiring board, and
wherein the plurality of NSMD type solder ball lands are arranged in upper and lower peripheral areas of the wiring board, and corner areas of the wiring board.

15. The semiconductor package of claim 9, wherein the chip comprises a single chip or a stacked chip.

16. A semiconductor package comprising:
a wiring board comprising a base substrate layer, a plurality of solder masks under the base substrate layer, a plurality of solder mask-defined (SMD) type solder ball lands arranged between the plurality of solder masks, and a plurality of non-solder mask defined (NSMD) type solder ball lands each arranged between the plurality of solder masks, wherein the base substrate layer is exposed between the plurality of NSMD type solder ball lands and the plurality of solder masks;
a chip provided on and electrically connected to the wiring board;
a molding layer provided on the chip and the wiring board;
a plurality of solder balls fused with the plurality of SMD type solder ball lands and the plurality of NSMD type solder ball lands; and
a substrate comprising a plurality of conductive pads fused with the plurality of solder balls.

17. The semiconductor package of claim 16, wherein the plurality of SMD type solder ball lands are wider than the plurality of NSMD type solder ball lands, and
wherein the plurality of NSMD type solder ball lands are electrically isolated from the chip.

18. The semiconductor package of claim 17, wherein the plurality of SMD type solder ball lands are located in a central area of the wiring board in a plan view, and the plurality of NSMD type solder ball lands are located in corner areas of the wiring board in the plan view.

19. The semiconductor package of claim 17, wherein the wiring board extends in an X direction and a Y direction,
wherein the plurality of NSMD type solder ball lands are arranged in a first column and a second column that both extend in the Y direction, and
wherein the plurality of SMD type solder ball lands are arranged in a plurality of columns spaced apart in the X direction and extending in the Y direction in a central area of the wiring board between the first column and the second column.

20. The semiconductor package of claim 17, wherein the chip comprises a single chip or a stacked chip.
